(19) United States
(12) Patent Application Publication
(10) Pub. No.: US 2013/0126850 A1
(43) Pub. Date: May 23, 2013

(54) RADIATION DETECTOR AND RADIATION DETECTOR MANUFACTURING METHOD

(71) Applicant: FUJIFILM CORPORATION, Tokyo (JP)

(72) Inventors: Naoto IWAKIRI, Ashigarakami-gun (JP); Haruyasu NAKATSUGAWA, Ashigarakami-gun (JP); Yasunori OHTA, Ashigarakami-gun (JP); Naoyuki NISHINOU, Ashigarakami-gun (JP)

(73) Assignee: FUJIFILM CORPORATION, Tokyo (JP)

(21) Appl. No.: 13/744,432

(22) Filed: Jan. 18, 2013

Related U.S. Application Data
(63) Continuation of application No. PCT/JP2011/066267, filed on Jul. 15, 2011.

(30) Foreign Application Priority Data
Jul. 27, 2010 (JP) 2010-168583
Jul. 28, 2010 (JP) 2010-169444

(51) Int. Cl. H01L 51/42; H01L 51/00

(52) U.S. Cl. CPC H01L 51/42; H01L 51/0001
USPC 257/40; 257/53; 438/96

(57) ABSTRACT

A radiation detector that includes a first scintillator layer, an organic photoelectric conversion layer and a substrate is provided. The first scintillator layer, the organic photoelectric conversion layer and the substrate are layered along a radiation incident direction. The first scintillator layer contains a blend of a first phosphor material that is mainly sensitive to low energy radiation in incident radiation and converts the radiation into light of a first wavelength, and a second phosphor material that is more sensitive to high energy than low energy radiation in the radiation and converts the radiation into light of a second wavelength different from the first wavelength. The organic photoelectric conversion layer is configured by disposing a plurality of first light detection sensors and a plurality of second light detection sensors in the same plane.

This application is a continuation application of International Application No. PCT/JP2011/066267, filed Jul. 15, 2011, which is incorporated herein by reference. Further, this application claims priority from Japanese Patent Application No. 2010-168583, filed Jul. 27, 2010, and Japanese Patent Application No. 2010-169444, filed Jul. 28, 2010, which are incorporated herein by reference.

### BACKGROUND OF THE INVENTION

1. Technical Field

The present invention relates to a radiation detector and a radiation detector manufacturing method.

2. Related Art

Recently, radiation detectors are being put into practice such as flat panel detectors (FPDs) with an X-ray sensitive layer disposed on a Thin Film Transistor (TFT) active matrix substrate and capable of directly converting X-ray data into digital data. Such radiation detectors have advantages over traditional imaging plates in that images can be checked immediately and video images can also be checked, and they are rapidly becoming widely used.

Various types of such radiation detectors are proposed. For example, there are direct conversion methods wherein X-rays are directly converted into charge and stored by a semiconductor layer and indirect conversion methods wherein X-rays are first converted into light by a scintillator (a wavelength conversion section) configured for example from CsI:Tl or GOS (Gd₂O₂S:Tb), and the converted light is then converted into charge by a light detection sensor such as a photodiode.

Technology is known in radiographic image capture wherein image capture of the same site of an imaging subject is performed at different X-ray tube voltages, and image processing (referred to below as subtraction image processing) is performed wherein a difference is computed with weightings applied to the radiographic images obtained by image capture at each X-ray tube voltage. A radiographic image is obtained in which, in the image (referred to below as an “energy subtraction image”) a first out of image portions corresponding to hard tissue such as bones and image portions corresponding to soft tissue is emphasized and the other is removed. For example, it is possible to see affected sites that are hidden by the ribs when an energy subtraction image corresponding to soft tissue in the chest region is employed, enabling an improvement in diagnostic capability.

However, when image capture is performed at different X-ray tube voltages, radiation irradiation is performed two times, leading to the concern that an image with good diagnostic capabilities may not be able to be obtained if for example the imaging subject moves.

Japanese National Phase Publication No. 2009-511871 discloses a radiation detector capable of obtaining two radiographic images, a soft tissue radiographic image (referred to below as a low-voltage image) expressing low energy radiation out of radiation that has been transmitted through the imaging subject and a hard tissue radiographic image (referred to below as a high voltage image) expressing high energy radiation therein, for a single time of radiation irradiation.

More specifically, this radiation detector is configured by stacked layers of a first scintillator layer that absorbs and converts radiation into light of a first wavelength, a second scintillator layer that absorbs and converts radiation into light of a second wavelength, a first light detection sensor that responds to (photoelectrically converts) the second wavelength light and does not respond to the first wavelength light, and a second light detection sensor that responds to (photoelectrically converts) the first wavelength light and does not respond to the second wavelength light.

However, in the configuration of Japanese National Phase Publication No. 2009-511871, the thickness of the radiation detector is increased due to the double layer structure of the first light detection sensor and the second light detection sensor. There is the concern that due to size relationships it might no longer be possible to incorporate the radiation detector into for example an electronic cassette when the thickness of the radiation detector increases.

### SUMMARY

In consideration of the above circumstances, an object of the present invention provides a radiation detector that has a thin thickness and is capable of obtaining two radiographic images for a single time of radiation irradiation, and a radiation detector manufacturing method thereof.

A radiation detector according to a first aspect of the present invention includes: a first scintillator layer containing a blend of a first phosphor material that is mainly sensitive to low energy radiation in incident radiation and converts the radiation into light of a first wavelength, and a second phosphor material that is mainly sensitive to high energy rather than low energy radiation in the radiation and converts the radiation into light of a second wavelength different from the first wavelength; an organic photoelectric conversion layer configured by disposing in the same plane plural first light detection sensors that are configured from a first organic material and that absorb and convert into charge more of the first wavelength light than the second wavelength light, and plural second light detection sensors that are configured from a second organic material different from the first organic material and that absorb and convert into charge more of the second wavelength light than the first wavelength light; and a substrate, the organic photoelectric conversion layer being disposed on the substrate and the substrate being formed with transistors that read the charges that have been generated in the organic photoelectric conversion layer. The first scintillator layer, the organic photoelectric conversion layer, and the substrate are layered along a radiation incident direction and

When radiation that has been transmitted through an imaging subject is irradiated onto the above configuration, the first phosphor material of the first scintillator layer is mainly sensitive to low energy radiation in the incident radiation and converts the radiation into the first wavelength light, and the second phosphor material of the first scintillator layer is mainly sensitive to high energy rather than low energy radiation in the incident radiation and converts the radiation into the second wavelength light. A low voltage image of soft tissue of the imaging subject expressing low energy radiation is obtained by the first light detection sensors absorbing and converting into charge more of the first wavelength light than the second wavelength light from the first scintillator layer. A high voltage image of hard tissue of the imaging subject expressing high energy radiation is obtained by the second light detection sensors absorbing and converting into charge more of the second wavelength light than the first wavelength light from the first scintillator layer.

It is accordingly possible to obtain two radiographic images, the low voltage image and the high voltage image, for a single time of radiation irradiation.

The organic photoelectric conversion layer is configured by disposing in the same plane plural of the first light detection sensors that absorb the first wavelength light and plural of the second light detection sensors that absorb the second wavelength light. The thickness of the organic photoelectric conversion layer can accordingly be made thinner than when the first light detection sensors and the second light detection sensors are configured with a double layer structure, and hence the radiation detector can also be made thinner overall.

A radiation detector according to a second aspect of the present invention includes: a first scintillator layer that is mainly sensitive to low energy radiation in incident radiation and converts the radiation into light of a first wavelength; a second scintillator layer that is mainly sensitive to high energy rather than low energy radiation in the radiation and converts the radiation into light of a second wavelength different from the first wavelength; an organic photoelectric conversion layer configured by disposing in the same plane plural first light detection sensors that are configured from a first organic material and that absorb and convert into charge more of the first wavelength light than the second wavelength light, and plural second light detection sensors that are configured from a second organic material different from the first organic material and that absorb and convert into charge more of the second wavelength light than the first wavelength light; and a substrate with light transmitting properties interposed between the first scintillator layer and the second scintillator layer with the organic photoelectric conversion layer formed on a face of the substrate and the substrate formed with transistors that read the charges that have been generated in the organic photoelectric conversion layer. The first scintillator layer, the second scintillator layer, the organic photoelectric conversion layer, and the substrate are layered along a radiation incident direction.

When radiation that has been transmitted through an imaging subject is irradiated onto the above configuration, the first scintillator layer is mainly sensitive to low energy radiation in the radiation and converts the radiation into the first wavelength light, and the second scintillator layer is mainly sensitive to high energy rather than low energy radiation in the radiation and converts the radiation into the second wavelength light different from the first wavelength. Then a low voltage image of soft tissue of the imaging subject expressing low energy radiation is obtained by the first light detection sensors absorbing and converting into charge more of the first wavelength light than the second wavelength light from the first scintillator layer. A high voltage image of hard tissue of the imaging subject expressing high energy radiation is also obtained by the second light detection sensors absorbing and converting into charge more of the second wavelength light than the first wavelength light from the second scintillator layer.

It is accordingly possible to obtain two radiographic images, the low voltage image and the high voltage image, for a single time of radiation irradiation.

The organic photoelectric conversion layer is configured by disposing in the same plane plural of the first light detection sensors that absorb the first wavelength light and plural of the second light detection sensors that absorb the second wavelength light. The thickness of the organic photoelectric conversion layer can accordingly be made thinner than when the first light detection sensors and the second light detection sensors are configured with a double layer structure, and hence the radiation detector can also be made thinner overall.

A radiation detector according to a third aspect of the present invention is the first aspect wherein the substrate has light transmitting properties, and a second scintillator layer configured from the same material as the first scintillator layer is disposed on the substrate.

According to the above configuration, the light emitted by the second scintillator layer hits the organic photoelectric conversion layer after being transmitted through the substrate with light transmitting properties. The second scintillator layer accordingly serves a similar role to the first scintillator layer, and the thickness of the first scintillator layer can be made thinner by the amount of the second scintillator layer disposed on the substrate side. When the thickness of the first scintillator layer is thin, even supposing the radiation is irradiated in sequence to the first scintillator layer, the organic photoelectric conversion layer, the substrate and the second scintillator layer, there is a closer separation between the scintillator portion in the first scintillator layer that mainly absorbs the radiation and the organic photoelectric conversion layer, more light is absorbed by the organic photoelectric conversion layer and the sensitivity is raised.

A radiation detector according to a fourth aspect of the present invention is the first aspect wherein the substrate side is set as the radiation incident face.

According to the above configuration, the radiation is irradiated in sequence to the substrate, the organic photoelectric conversion layer and the first scintillator layer. When this occurs, the radiation is first irradiated to the portion of the scintillator on the organic photoelectric conversion layer, and it is mostly this photoelectric conversion layer side scintillator portion that absorbs radiation and emits light. Since the portion of the first scintillator layer that mainly absorbs radiation and emits light is on the photoelectric conversion layer side, this scintillator portion and the organic photoelectric conversion layer are disposed with a close separation, and so more light is absorbed by the organic photoelectric conversion layer, and the sensitivity is raised.

A radiation detector according to a fifth aspect of the present invention is any one of the first aspect to the fourth aspect wherein the total light receiving surface area of the first light detection sensors and the second light detection sensors are the same as each other.

According to the above configuration, the first light detection sensors and the second light detection sensors can be made to receive the same amount of light as each other.

A radiation detector according to a sixth aspect of the present invention is the fifth aspect wherein the first light detection sensors and the second light detection sensors respectively configure single pixels of a radiographic image expressing radiation that has been transmitted through an imaging subject.

According to the above configuration, a single pixel of a radiographic image is obtained with a single light detection sensor.

A radiation detector according to a seventh aspect of the present invention is the radiation detector of the sixth aspect wherein plural of the first light detection sensors and plural of the second light detection sensors are disposed at a ratio of 1 to 1 so as to be adjacent to each other.

According to the above configuration, low voltage images and high voltage images are obtained at the same resolution.

A radiation detector according to an eighth aspect of the present invention is the sixth aspect wherein more of the first light detection sensors are disposed than the second light detection sensors.

According to the above configuration, by increasing the number of first light detection sensors that absorb and convert into charge the first wavelength light converted from radiation by being sensitive to more low energy radiation than high energy radiation in the incident radiation, the number of pixels in the low voltage images obtained from the first light detection sensors is increased, enabling the resolution of the low voltage images to be raised. Raising the resolution of the low voltage images representing soft tissue of the imaging subject enables fine structures of the soft tissue to be more reliably visually checked in comparison to the configuration of the sixth aspect above.

A radiation detector according to a ninth aspect of the present invention is the eighth aspect wherein the second light detection sensors are disposed surrounded in four directions by plural of the first light detection sensors.

According to the above configuration, the pixels in the center portions surrounded on four sides can be supplemented with good precision as low voltage image pixels by employing the pixels obtained by plural of the first light detection sensors on the four sides thereof.

A radiation detector according to a tenth aspect of the present invention is any one of the first aspect to the ninth aspect wherein: the first light detection sensor transmits light of the second wavelength and absorbs light of the first wavelength; and the second light detection sensor transmits light of the first wavelength and absorbs light of the second wavelength.

According to the above configuration, due to the first light detection sensors transmitting and not absorbing the light of the second wavelength from the first scintillator layer and absorbing and converting into charge the light of the first wavelength, clearer low voltage images expressing the low energy radiation can be obtained in a manner that does not include high voltage images expressing the high energy radiation. Moreover, due to the second light detection sensor transmitting and not absorbing the light of the first wavelength from the first scintillator layer and absorbing and converting into charge the light of the second wavelength, clearer high voltage images expressing the high energy radiation can be obtained in a manner that does include low voltage images expressing the low energy radiation.

A radiation detector according to an eleventh aspect of the present invention is any one of the first aspect to the ninth aspect wherein the first wavelength is a blue light wavelength and the second wavelength is a green light wavelength.

In this way, by distinguishing the colors of the first wavelength light and the second wavelength light emitted by the scintillator layer, the wavelength regions of the emitted light can be prevented from overlapping with each other, and the generation of noise can be suppressed.

A radiation detector according to a twelfth aspect of the present invention is the third aspect wherein the first scintillator layer and the second scintillator layer contain as the first phosphor material and the second phosphor material Tb doped Gd₂O₂S that converts radiation into green light and Eu doped BaFX that converts the radiation into blue light (wherein X is a halogen).

According to the above configuration, the absorption of unwanted light by the organic photoelectric conversion layer can be suppressed since the first scintillator layer and the second scintillator layer emit light with sharp wavelengths, namely emit light that hardly contains colors other than green and blue.

A radiation detector according to a thirteenth aspect of the present invention is the second aspect wherein: the first scintillator layer is configured with Eu doped BaFX (wherein X is a halogen) that converts the radiation into blue light; and the second scintillator layer is configured with Tb doped Gd₂O₂S that converts radiation into green light.

According to the above configuration, the absorption of unwanted light by the organic photoelectric conversion layer can be suppressed since the first scintillator layer emits light with a sharp wavelength, namely light that hardly contains any colors other than blue, and the second scintillator layer emits light with a sharp wavelength, namely light that hardly contains any colors other than green.

A radiation detector according to a fourteenth aspect of the present invention is the first aspect to the thirteenth aspect wherein an active layer of the transistor is configured with an amorphous oxide material, and the substrate is configured with a plastic resin.

According to the above configuration, since the organic photoelectric conversion layer is configured with an organic material and the active layer of the transistor is configured with an amorphous oxide material, the manufacture of the radiation detector is possible entirely with low temperature processes, enabling the substrate to be configured with a flexible plastic resin that generally also has low heat resistance. Employing such a flexible plastic substrate allows a reduction in weight to be achieved, which is advantageous for example from perspectives such as portability.

A radiation detector according to a fifteenth aspect of the present invention is the second aspect or the thirteenth aspect wherein the first scintillator layer has a columnar structure.

According to the above configuration, light converted in the first scintillator layer can progress in the columnar structure while being reflected at the boundaries of the columnar structure, and light scattering is reduced. Consequently, the amount of light received by the first light detection sensors of the organic photoelectric conversion layer is greater, such that a high quality low voltage image can be obtained.

A radiation detector manufacturing method according to a sixteenth aspect of the present invention is a manufacturing method for the radiation detector of any one of the first aspect to the fourth aspect, and includes disposing plural of the first light detection sensors and plural of the second light detection sensors of the organic photoelectric conversion layer on the substrate in the same plane as each other using an inkjet method.

According to the above method, configuring the photoelectric conversion layer of the radiation detector from an organic material enables an inkjet method to be employed when disposing (forming) the photoelectric conversion layer. Employing such an inkjet method enables the first light detection sensors and the second light detection sensors that are configured from different organic materials to be easily disposed in the same plane. Moreover, the thickness of the first light detection sensors and the second light detection sensors can be regulated by overprinting liquids containing organic material with an inkjet method.

According to the present invention, a radiation detector with a thin thickness can be provided that is capable of obtaining two radiographic images for a single time of radiation irradiation, and a radiation detector manufacturing method thereof can also be provided.

### BRIEF DESCRIPTION OF THE DRAWINGS

FIG. 1 is a schematic view illustrating the disposal of an electronic cassette during radiographic image capture;

FIG. 2 is a schematic perspective view illustrating an internal structure of an electronic cassette;

FIG. 3 is a cross-section illustrating a cross-sectional configuration of a radiation detector according to a first exemplary embodiment of the present invention;

FIG. 4 is a diagram illustrating a relationship between wavelength and spectral characteristics;

FIG. 5 is a cross-section illustrating in detail the configuration of the radiation detector illustrated in FIG. 3;

FIG. 6 is a drawing schematically illustrating a configuration of a TFT switch;

FIG. 7 is a drawing illustrating a wiring structure of a TFT substrate;

FIG. 8 is a drawing to explain operation of a radiation detector according to the first exemplary embodiment of the present invention;

FIG. 9 is a cross-section illustrating a cross-sectional configuration of a radiation detector according to a second exemplary embodiment of the present invention;

FIG. 10 is a cross-section illustrating a cross-sectional configuration of a radiation detector according to a third exemplary embodiment of the present invention;

FIG. 11 is a drawing to explain operation of a radiation detector according to the third exemplary embodiment of the present invention;

FIG. 12 is a drawing illustrating a placement ratio of first light detection sensors and second light detection sensors in a radiation detector according to the first exemplary embodiment to the third exemplary embodiment of the present invention;

FIG. 13 is a drawing illustrating a modified example of a placement ratio of first light detection sensors and second light detection sensors in a radiation detector according to the first to the third exemplary embodiments of the present invention; and

FIG. 14 is a drawing illustrating a modified example of a placement ratio of first light detection sensors and second light detection sensors in a radiation detector according to the first exemplary embodiment to the third exemplary embodiment of the present invention.

### DETAILED DESCRIPTION OF THE INVENTION

### First Exemplary Embodiment

Specific explanation follows regarding a radiation detector and a manufacturing method of a radiation detector according to a first exemplary embodiment of the present invention, with reference to the accompanying drawings. Note that in the drawings members (configuration elements) having the same or corresponding functions are allocated the same reference numerals and further explanation is omitted as appropriate.

—Radiographic Image Capture Device Configuration—

Explanation first follows regarding a configuration of an electronic cassette as an example of a radiographic image capture device according to the first exemplary embodiment of the present invention.

The electronic cassette according to the first exemplary embodiment of the present invention is a radiographic image capture device configured to be portable, detect radiation from a radiation source that has been transmitted through an imaging subject, generate image data of a radiographic image expressing the detected radiation, and be capable of storing the generated image data, and is specifically configured as laid out below. Note that the electronic cassette may also be configured so as not to store the generated image data.

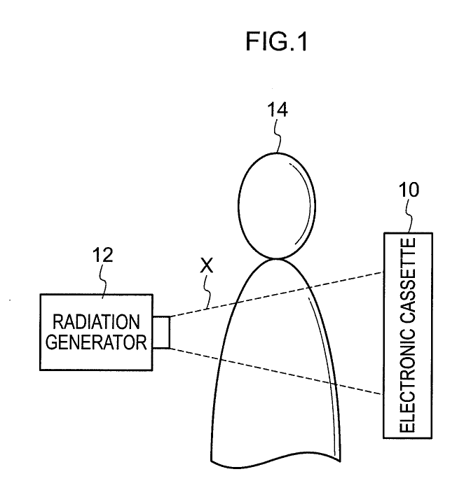

FIG. 1 is a schematic diagram illustrating the placement of the electronic cassette during radiographic image capture.

During radiographic image capture an electronic cassette 10 is disposed at a separation to a radiation generator 12 serving as a radiation source that generates radiation X. An image capture position for positioning a patient 14 as the imaging subject is present at this stage between the radiation generator 12 and the electronic cassette 10. When radiographic image capture is instructed, the radiation generator 12 emits the radiation X at a radiation amount according to pre-supplied image capture conditions. The radiation X emitted from the radiation generator 12 is irradiated onto the electronic cassette 10 after picking up image data by being transmitted through the patient 14 positioned at the image capture position.

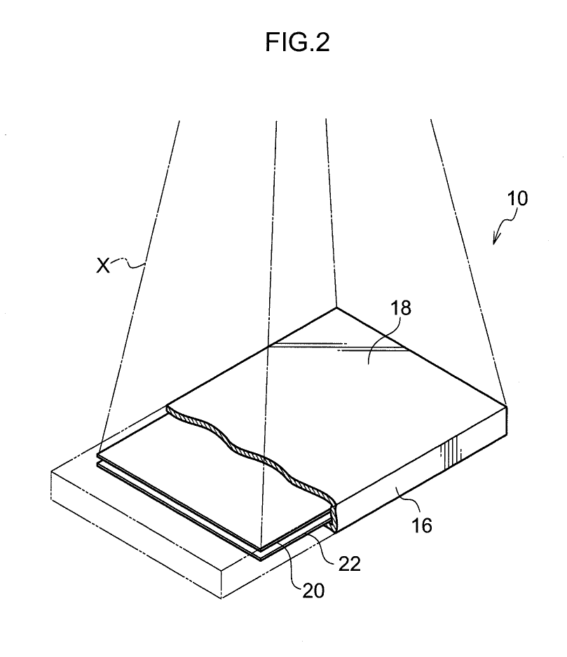

FIG. 2 is a schematic perspective view illustrating the internal structure of the electronic cassette 10.

The electronic cassette 10 is equipped with a flat plate shaped casing 16 made at a specific thickness from a material that allows the radiation X to be transmitted through. Inside the casing 16 are, provided in sequence from an incident face 18 of the casing 16 onto which the radiation X is irradiated, a radiation detector 20 that detects the radiation X that has been transmitted through the patient 14, and a control board 22 that controls the radiation detector 20.

—Radiation Detector 20 Configuration—

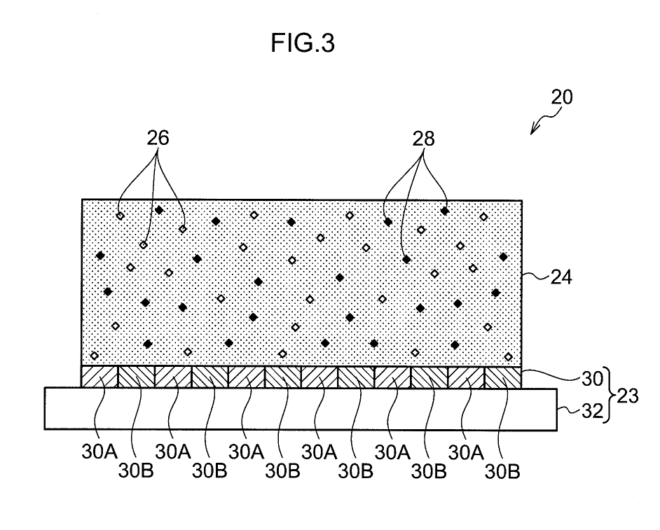

Explanation follows regarding a configuration of the radiation detector 20 according to the first exemplary embodiment of the present invention. FIG. 3 is a cross-section illustrating a cross-section configuration of the radiation detector 20 according to the first exemplary embodiment of the present invention.

The radiation detector 20 according to the first exemplary embodiment of the present invention has a rectangular flat plate shape, detects the radiation X that has been transmitted through the patient 14 as described above, and captures a radiographic image expressing the radiation X, and has a scintillator layer 24 formed on a light detection substrate 23, described later.

The scintillator layer 24 is configured containing a blend of two types of phosphor material with mutually different sensitivities (K absorption edge and light emission wavelength) to the radiation X. Specifically, a blend is contained of: a first phosphor material 26 with radiation absorption ratio μ that does not have a K absorption edge in a high energy portion, namely in which there is no discontinuous increase in the absorption ratio μ in the high energy portion, for capturing a low voltage image of soft tissue expressing low energy radiation out of the radiation X that has been transmitted through the patient 14; and a second phosphor material 28 with radiation absorption ratio μ higher in the high energy portion than that of the first phosphor material 26, for capturing a high voltage image of hard tissue expressing high energy radiation out of the radiation X that has been transmitted through the patient 14.

Note that reference to “soft tissue” means tissue other than bone tissue such as cortical bone and/or spongy bone, and includes tissue such as muscle and internal organs. Reference to “hard tissue” means bone tissue such as cortical bone and/or spongy bone.

The first phosphor material 26 and the second phosphor material 28 may be appropriately selected from all the materials generally employed in scintillators as long as they are phosphor materials with mutually different sensitivities to radiation X. For example two types may be selected from the phosphor materials listed in the following Table 1. Note that from the perspective of clearly discriminating the low voltage images and the high voltage images obtained by image capture, the first phosphor material 26 and the second phosphor material 28 preferably not only have mutually different sensitivities to radiation X but also have mutually different light emission colors.

TABLE 1

| | Light Emission | Wavelength | K Absorption |
|---|---|---|---|
| Composition | Color | (nm) | Edge (eV) |
| HfP₂O₇ | Ultraviolet | 300 | 65.3 |
| YTaO₄ | Ultraviolet | 340 | 67.4 |
| BaSO₄: Eu | Violet | 375 | 37.4 |
| BaFCl: Eu | Violet | 385 | 37.4 |
| BaFBr: Eu | Violet | 390 | 37.4 |
| YTaO₄: Nb | Blue | 410 | 67.4 |
| CsI: Na | Blue | 420 | 36/33.2 |
| CaWO₄ | Blue | 425 | 69.5 |
| ZnS: Ag | Blue | 450 | 9.7 |
| LaOBr: Tm | Blue | 460 | 38.9 |
| Bi₄Ge₃O₁₂ | Blue | 480 | 90.4 |
| CdSO₄ | Blue-green | 480 | 27/69.5 |
| LaOBr: Tb | Bluish-white | 380, 415, 440, | 38.9 |
| | | 545 | |
| Y₂O₂S: Tb | Bluish-white | 380, 415, 440, | 17.03 |
| | | 545 | |
| Gd₂0₂S: Pr | Green | 515 | 50.2 |
| (Zn,Cd) S: Ag | Green | 530 | 9.7/27 |
| CsI: Tl | Green | 540 | 36/33.2 |
| Gd₂O₂S: Tb | Green | 545 | 60.2 |
| La₂O₂S: Tb | Green | 545 | 38.9 |

Examples of other phosphor materials not included in Table 1 that may be selected include: CsBr:Eu, ZnS:Cu, Gd₂O₂S:Eu, Lu₂O₂S:Tb.

However, from the perspective of being readily formed without delinquency preferably a material is selected from the above with a base material other than CsI or CsBr.

From the perspective of performing image capture without color filters to absorb (block) light of specific wavelengths without imparting noise to captured radiographic images, preferably out of the above a material is employed that is other than CsI:Tl, (Zn, Cd) S:Ag, CaWO₄:Pb, La₂OBr:Tb, ZnS:Ag, or CsI:Na and that emits light with sharp (narrow emission light wavelengths) rather than broad wavelengths. Examples of phosphor materials that emit light with such sharp wavelengths include green light emitting Gd₂O₂S:Tb and La₂O₂S:Tb, and blue light emitting BaFX:Eu, (wherein X is a halogen such as Br or Cl). A combination from the above of the green light emitting Gd₂O₂S:Tb and the blue light emitting BaFX:Eu is particularly preferable for the first phosphor material 26 and the second phosphor material 28.

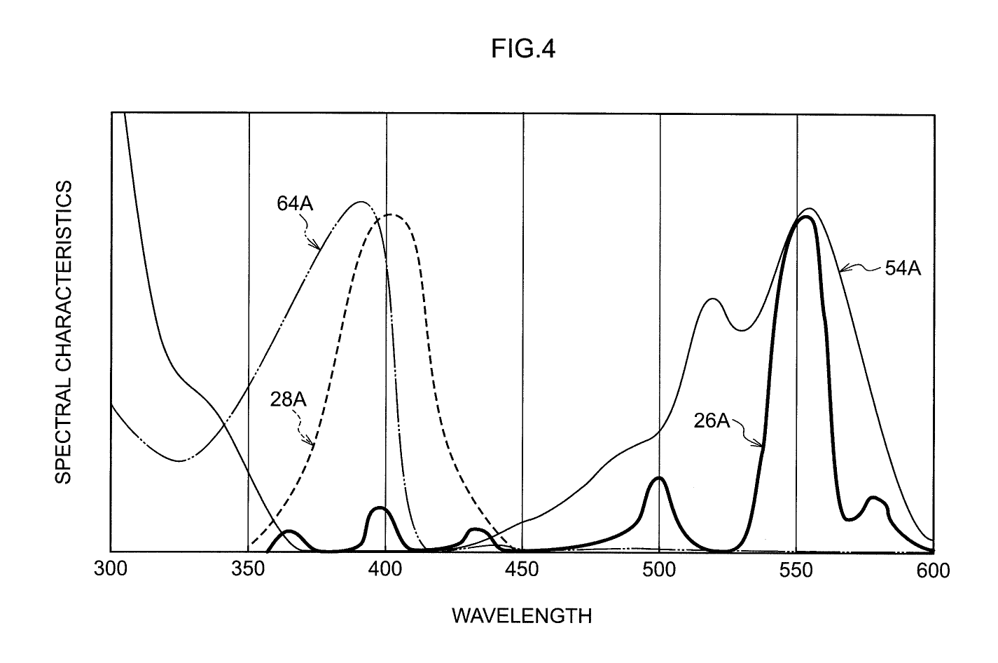

The first phosphor material 26 and the second phosphor material 28 are selected to have mutually different sensitivities to radiation X and to have mutually different emission light wavelength peaks. As illustrated in FIG. 4, the first phosphor material 26 is sensitive to mainly low energy radiation from out of incident radiation X and converts radiation X into light 26A with a peak at a first wavelength. The second phosphor material 28 is sensitive to mainly high energy rather than low energy radiation from the radiation X and converts the radiation X into light 28A with a peak at a second wavelength different from the first wavelength.

Note that in FIG. 4 illustrates an example of spectral characteristics of the respective phosphor materials 26, 28 for a case in which the first phosphor material 26 is green light emitting Gd₂O₂S:Tb, and the second phosphor material 28 is violet light emitting BaFBr:Eu. However, the spectral characteristics of the first phosphor material 26 and the second phosphor material 28 may be spectral characteristics with other profiles as long as they do not depart from the principles described above. Moreover, although the first wavelength is illustrated in FIG. 4 as a longer wavelength than the second wavelength, it may be shorter. The horizontal axis in FIG. 4 illustrates light wavelength, and the vertical axis illustrates spectral characteristics, namely the relative emission light intensities.

Returning to FIG. 3, the light emitted by the scintillator layer 24 is light received by the light detection substrate 23. The light detection substrate 23 is equipped with an organic photoelectric conversion layer 30 and a TFT active matrix substrate 32 (referred to below as TFT substrate).

The organic photoelectric conversion layer 30 is interposed between the scintillator layer 24 and the TFT substrate 32, and is employed to receive light emitted by the scintillator layer 24 and convert the received light into charge. Specifically, configuration is made with plural first light detection regions 30A and plural second light detection regions 30B disposed in the same plane and with at least a portion configured from organic materials having different light absorption characteristics. The plural first light detection regions 30A and the plural second light detection regions 30B are for example disposed mutually adjacent to each other in the same flat plane at a 1:1 ratio in a staggered formation.

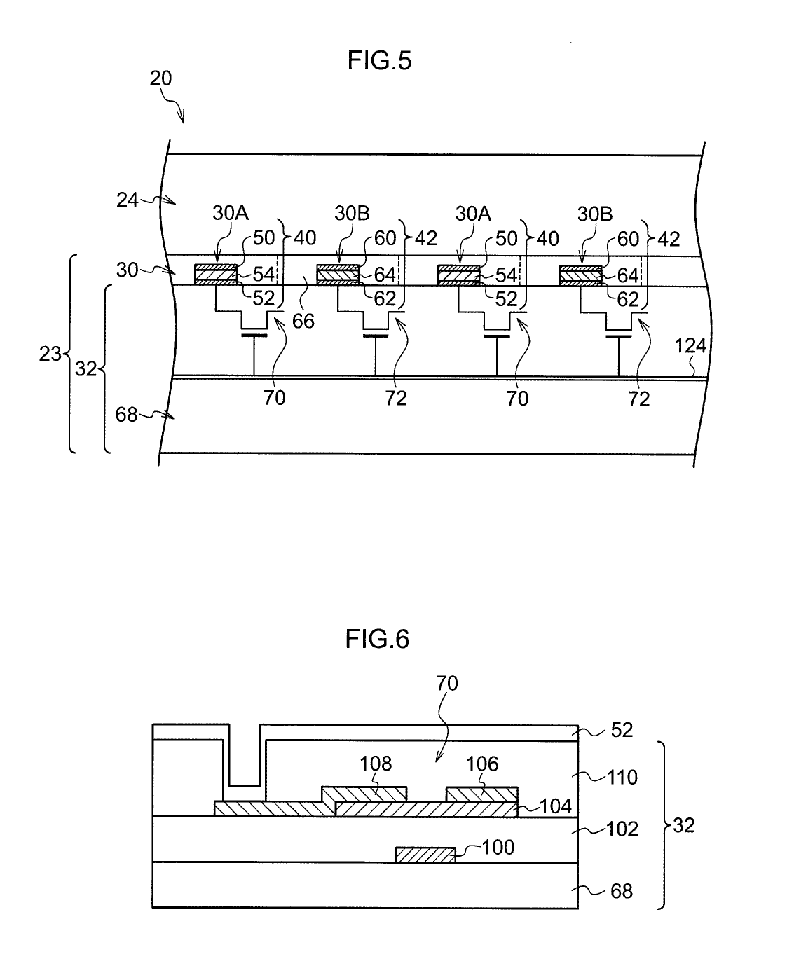

FIG. 5 is a cross-section illustrating details of the configuration of the radiation detector 20 illustrated in FIG. 3.

As illustrated in FIG. 5, first light detection sensors 40 are formed in the first light detection regions 30A of the organic photoelectric conversion layer 30, and second light detection sensors 42 having the same total light receiving surface area as the total light receiving surface area of the first light detection sensors 40 are formed in the second light detection regions 30B of the organic photoelectric conversion layer 30. The first light detection sensors 40 and the second light detection sensors 42 each respectively configure single pixels of radiographic images expressing radiation X that has been transmitted through the patient 14.

The first light detection sensors 40 include an upper electrode 50, a lower electrode 52, and a first organic photoelectric conversion layer 54 interposed between the upper and lower electrodes. The second light detection sensors 42 include an upper electrode 60, a lower electrode 62, and a second organic photoelectric conversion layer 64 interposed between the upper and lower electrodes, and having different light absorption characteristics to those of the first organic photoelectric conversion layer 54.

The first organic photoelectric conversion layer 54 absorbs more of the first wavelength light 26A emitted from the first phosphor material 26 than the second wavelength light 28A, and converts the absorbed light into charges according to the absorbed light, namely generates charges. Such light absorption characteristics of the first organic photoelectric conversion layer 54 are for example characteristics 54A, as illustrated in FIG. 4. By adopting such a configuration, noise due to the second wavelength light 28A being absorbed by the first organic photoelectric conversion layer 54 can be effectively suppressed from occurring since the second wavelength light 28A is not absorbed as much as the first wavelength light 26A.

The second organic photoelectric conversion layer 64 is employed to absorb more of the second wavelength light 28A emitted from the second phosphor material 28 than the first wavelength light 26A, and convert the absorbed light into charges according to the absorbed light, namely to generate charges. Such light absorption characteristics of the second organic photoelectric conversion layer 64 are for example characteristics 64A illustrated in FIG. 4. By adopting such a configuration, noise due to the first wavelength light 26A being absorbed by the second organic photoelectric conversion layer 64 can be effectively suppressed from occurring since the first wavelength light 26A is not absorbed as much as the second wavelength light 28A.

Note that from the perspective of suppressing the above noise, preferably the first organic photoelectric conversion layer 54 for example transmits 95% or more of the second wavelength light 28A and selectively absorbs the first wavelength light 26A, and the second organic photoelectric conversion layer 64 for example transmits 95% or more of the first wavelength light 26A and selectively absorbs the second wavelength light 28A. More preferably the first organic photoelectric conversion layer 54 transmits all of the second wavelength light 28A and selectively absorbs the first wavelength light 26A, and the second organic photoelectric conversion layer 64 transmits all the first wavelength light 26A and selectively absorbs the second wavelength light 28A.

Moreover, FIG. 4 illustrates an example of the spectral characteristics of each of the organic photoelectric conversion layers 54, 64 in a case where the first organic photoelectric conversion layer 54 is configured from green-absorbing quinacridone and the second organic photoelectric conversion layer is configured from a combination of a p-type substance containing blue-absorbing rubrene and an n-type substance containing fullerene or higher fullerene. However the spectral characteristics of the first organic photoelectric conversion layer 54 and the second organic photoelectric conversion layer 64 may be any spectral characteristics provided that they do not depart from the above principles. Note that the horizontal axis in FIG. 4 shows light wavelength, and the vertical axis shows spectral characteristics, namely light absorbance characteristics.

The function described above can be realized by configuring the first organic photoelectric conversion layer 54 and the second organic photoelectric conversion layer 64 from appropriately selected organic materials.

As well as the quinacridone and the combination of a p-type substance containing rubrene and an n-type substance containing fullerene or higher fullerene mentioned above, examples of materials for the first organic photoelectric conversion layer 54 and the second organic photoelectric conversion layer 64 include: red absorbing phthalocyanine and blue absorbing anthraquinone.

In order to configure the first organic photoelectric conversion layer 54 and the second organic photoelectric conversion layer 64 from organic materials, an inkjet method may be employed as the forming method for the first organic photoelectric conversion layer 54 and the second organic photoelectric conversion layer 64, in place of a generally employed vapor deposition method. Employing such an inkjet method allows the first organic photoelectric conversion layer 54 and the second organic photoelectric conversion layer 64 that are configured from different organic materials to be easily disposed in the same plane. Moreover, the thickness of the first organic photoelectric conversion layer 54 and the second organic photoelectric conversion layer 64 can be regulated by overprinting liquids containing organic material with an inkjet method.

A gap is formed between the first organic photoelectric conversion layer 54 and the second organic photoelectric conversion layer 64 such that charges respectively generated therein do not pass across between each other. A flattening layer 66 is filled in this gap to flatten over the TFT substrate 32.

Charges generated in the first organic photoelectric conversion layer 54 and the second organic photoelectric conversion layer 64 are read by the TFT substrate 32. The TFT substrate 32 is configured with plural TFT switches 70, 72 formed on a support substrate 68. The TFT switches 70 convert charges that have migrated from the first organic photoelectric conversion layer 54 into the lower electrode 52 into electrical signals and output the electrical signals. The TFT switches 72 convert charges that have migrated from the second organic photoelectric conversion layer 64 into the lower electrode 62 into electrical signals and output the electrical signals.

FIG. 6 is a diagram schematically illustrating a configuration of each of the TFT switches 70. Note that the TFT switches 72 are configured similarly to the TFT switches 70 and hence explanation thereof is omitted.

The region where the TFT switches 70 are formed has a portion that overlaps with the lower electrode 52 in plan view. Due to adopting such a configuration, the TFT switches 70 and the first light detection sensors 40 overlap with each other in the thickness direction for each of the pixel portions. Note that in order to minimize the surface area of (the pixel portions of the) radiation detector 20, the region where the TFT switches 70 are formed is preferably completely covered by the lower electrode 52.

Each of the TFT switches 70 is stacked with a gate electrode 100, a gate insulating film 102, and an active layer (channel layer) 104. A source electrode 106 and a drain electrode 108 are formed a specific spacing apart from each other on the active layer 104. An insulating film 110 is further provided between the TFT switch 70 and the lower electrode 52.

The active layer 104 of the TFT switch 70 is preferably formed from an amorphous oxide material. As these amorphous oxide materials, preferable oxide materials include at least one of In, Ga, and Zn (for example In—O amorphous oxide materials), with oxide materials including at least two of In, Ga, and Zn (for example In—Zn—O based, In—Ga based, or Ga—Zn—O based) more preferred, and oxide materials including In, Ga, and Zn particularly preferred. As such an In—Ga—Zn—O amorphous oxide material, an amorphous oxide material whose composition in a crystalline state would be expressed by InGaO₃(ZnO)ₘ (where m is an integer less than 6) is preferred and InGaZnO₄ is particularly preferred.

Radiation such as X-rays is not absorbed, or any absorption is restricted to an extremely minute absorption amount, when the active layer 104 of the TFT switch 70 is configured from an amorphous oxide material. Generation of noise can accordingly be effectively suppressed.

Moreover, it is possible to form the amorphous oxide material and the organic materials configuring the first organic photoelectric conversion layer 54 and the second organic photoelectric conversion layer 64 at low temperature. Accordingly, when the active layer 104 is configured by an amorphous oxide material, the support substrate 68 is not limited to substrates with a high temperature resistance such as semiconductor substrates, quartz substrates, or glass substrates, and for example a plastic flexible substrate employing aramids or bionanofibers can therefore be employed as the support substrate 68. Specifically, flexible substrates such as polyesters, for example polyethylene terephthalate, polybutylene phthalate, and polyethylene naphthalate, polystyrene, polycarbonate, polyethersulphone, polyarylate, polyimide, polycyclic olefin, norbornene resin, and poly (chloro-trifluoro-ethylene) can be employed. Employing such a plastic flexible substrate enables a reduction in weight to be achieved, which is advantageous from the perspective of for example portability. Other layers may also be provided to the support substrate 68, such as an insulating layer to secure insulation, a gas barrier layer to prevent the transmission of moisture and/or oxygen, and/or an undercoat layer to improve flatness or adhesion to for example the electrodes.

High-temperature processing at 200 degrees or higher can be applied to aramids, enabling a transparent electrode material to be cured at a high temperature to give a low resistance, and aramids are also compatible with automatic packaging of driver ICs including solder reflow processing. Aramids also have a thermal expansion coefficient that is close to that of indium tin oxide (ITO) or a glass substrate, so post manufacture warping is small and they do not break easily. Aramids can also form a thinner substrate than for example a glass substrate. An ultrathin glass substrate and an aramid may also be layered together to form the support substrate 68.

Bionanofibers are composites of cellulose microfibril bundles (bacterial cellulose) produced by a bacterium (Acetobacter xylinum) and a transparent resin. Cellulose microfibril bundles have a width of 50 nm, a size that is 1/10 visible wavelengths, and also have high strength, high elasticity, and low thermal expansion. By impregnating bacterial cellulose with a transparent resin such as an acrylic resin or an epoxy resin and curing, bionanofibers can be obtained that exhibit a light transmittance of about 90% to 500 nm wavelength whilst including fibers at 60 to 70%. Bionanofibers have a low thermal expansion coefficient (3 to 7 ppm) comparable to silicon crystals, a strength comparable to steel (460 MPa), high elasticity (30 GPa), and are flexible, enabling the structure substrate 68 to be formed thinner than for example a glass substrate.

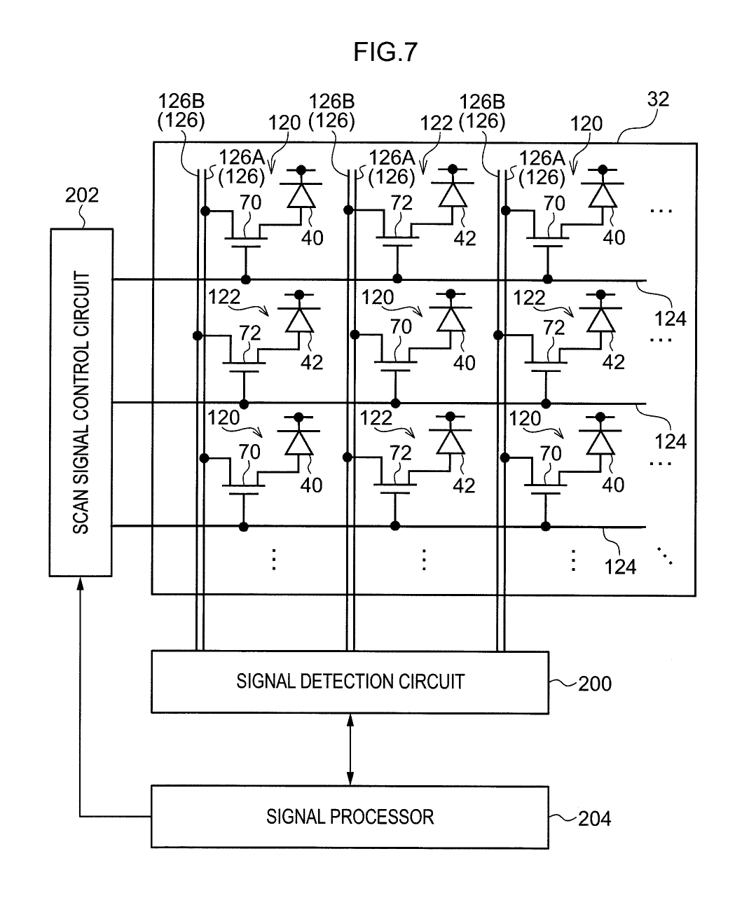

FIG. 7 is a diagram illustrating a wiring structure of the TFT substrate 32.

The TFT substrate 32 is, as illustrated in FIG. 7, provided with plural pixels 120 configured including the first light detection sensors 40 and the TFT switches 70 described above, and plural pixels 122 configured including the second light detection sensors 42 and the TFT switches 72 described above. The pixels 120 and the pixels 122 are alternately disposed in a two dimensional array along a specific direction (the row direction in FIG. 7) and a direction intersecting with the specific direction (the column direction in FIG. 7).

The TFT substrate 32 is provided with scan lines 124 that are provided for each of the pixel rows parallel to the specific direction, and signal lines 126 that are provided for each of the pixel rows parallel to the intersecting direction. Each of the signal lines 126 is configured from two signal lines, a first signal line 126A corresponding to the pixels 120, and a second signal line 126B corresponding to the pixels 122.

The sources of the TFT switches 70 are connected to the first light detection sensors 40, the drains are connected to the first signal lines 126A, and the gates are connected to the scan lines 124. The sources of the TFT switches 72 are connected to the second light detection sensors 42, the drains are connected to the second signal lines 126B, and the gates are connected to the scan lines 124.

In each of the first signal lines 126A an electrical signal flows according to the charge amount that was generated and accumulated in each of the first light detection sensors 40 by switching ON any of the TFT switches 70 connected to the first signal lines 126A. In each of the second signal lines 126B an electrical signal flows according to the charge amount that was generated and accumulated in each of the second light detection sensors 42 by switching ON any of the TFT switches 72 connected to the second signal lines 126B.

Each of the first signal lines 126A and the second signal lines 126B is connected to a signal detection circuit 200 that detects electrical signals flow out from the respective lines, and is connected to a scan signal control circuit 202 that outputs control signals to each of the scan lines 124 to switch the TFT switches 70, 72 in each of the scan lines 124 ON/OFF. Note that the signal detection circuit 200 and the scan signal control circuit 202 are provided to the control board 22 (see FIG. 2).

The signal detection circuit 200 is installed with amplifier circuits to amplify input electrical signals for each of the respective first signal lines 126A and the second signal lines 126B. By amplifying and detecting the electrical signals input from each of the first signal lines 126A and each of the second signal lines 126B in each of the amplifier circuits in the signal detection circuit 200, the charge amount generated in the first light detection sensor 40 of each of the pixels 120 is respectively detected as data of each of the pixels configuring a low voltage image, and the charge amount generated in the second light detection sensors 42 of each of the pixels 122 is respectively detected as data of each of the pixels configuring a high voltage image.

The signal detection circuit 200 and the scan signal control circuit 202 are connected to a signal processor 204 that: separates the data for each of the pixels detected by the signal detection circuit 200 into the image data from each of the first signal lines 126A and the image data from each of the second signal lines 126B and subjects the data to specific processing; outputs to the signal detection circuit 200 a control signal representing a timing for signal detection; and outputs to the scan signal control circuit 202 a control signal representing a timing for scan signal output.

The signal processor 204 is provided to the control board 22 (see FIG. 2), and, as the specific processing, performs processing to obtain a low voltage image by for example supplementing lacking pixel data in the image data obtained from the first signal lines 126A using the pixels 120 surrounding such pixels. Processing is also performed to obtain a high voltage image by for example supplementing lacking pixel data in the image data obtained from the second signal lines 126B using the pixels 122 surrounding such pixels. Furthermore, processing is performed when necessary to obtain an energy subtraction image by performing subtraction image processing using the obtained low voltage image and high voltage image.

—Operation—

Explanation follows regarding operation of the radiation detector 20 according to the first exemplary embodiment of the present invention.

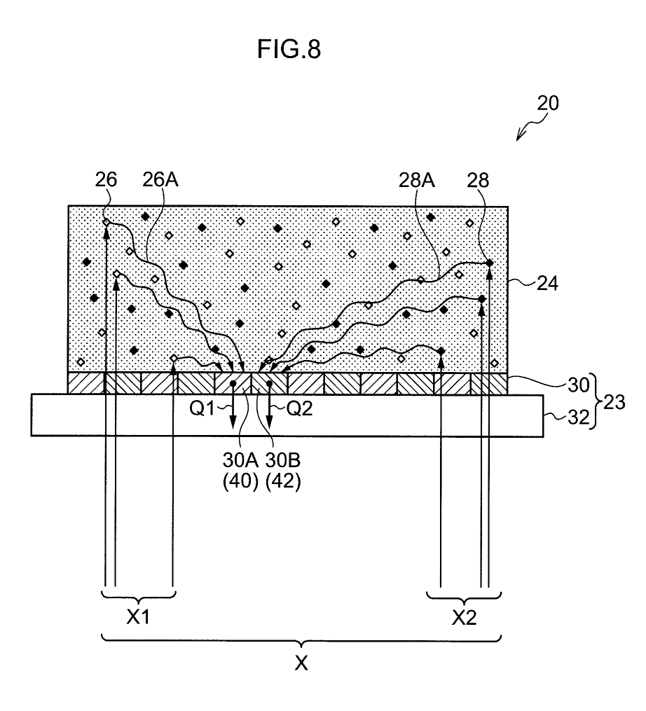

FIG. 8 is an explanatory diagram of the operation of the radiation detector 20 according to the first exemplary embodiment of the present invention.

As explained above, the radiation detector 20 according to the first exemplary embodiment of the present invention is configured with layers stacked in the radiation X incident direction including: the scintillator layer 24 containing a blend of the first phosphor material 26 that is mainly sensitive to low energy radiation from incident radiation X and converts the radiation X into light 26A with a peak at a first wavelength and the second phosphor material 28 that is mainly sensitive to high energy rather than low energy radiation from the incident radiation X and converts the radiation X into light 28A with a peak at a second wavelength different from the first wavelength; the organic photoelectric conversion layer 30 disposed to the scintillator layer 24 and including, disposed in the same plane, plural of the first light detection sensors 40 that are formed from an organic material and absorb and convert into charges more of the first wavelength light 26A than the second wavelength light 28A, and plural of the second light detection sensors 42 that are formed from a second organic material different from a first organic material and absorb and convert into charges more of the second wavelength light 28A than the first wavelength light 26A; and the TFT substrate 32 disposed to the organic photoelectric conversion layer 30 and formed with transistors that read the charges generated in the organic photoelectric conversion layer 30.

In such a configuration, when radiographic image capture is performed the radiation X that has been transmitted through the patient 14 is irradiated onto the radiation detector 20. The radiation X that has been transmitted through the patient 14 contains a low energy component and a high energy component. In the following the low energy component from the radiation X is referred to as low energy radiation X1 and the high energy component from the radiation X is referred to as high energy radiation X2.

In the radiation detector 20 according to the first exemplary embodiment of the present invention, since the radiation X incident face is the TFT substrate 32 side of the radiation detector 20, the irradiated radiation X hits the scintillator layer 24 after being transmitted through the TFT substrate 32 and the organic photoelectric conversion layer 30.

When the radiation X hits (is incident to) the scintillator layer 24, the first phosphor material 26 of the scintillator layer 24 is mainly sensitive to the low energy radiation X1 in the incident radiation X and converts the radiation X into the light 26A with a peak at the first wavelength. The second phosphor material 28 of the scintillator layer 24 is mainly sensitive to the high energy radiation X2 rather than low energy in the incident radiation X and converts the radiation X into the light 28A with a peak at the second wavelength. The first wavelength light 26A and the second wavelength light 28A are emitted from the scintillator layer 24 and hit the organic photoelectric conversion layer 30.

When the first wavelength light 26A and the second wavelength light 28A hit the organic photoelectric conversion layer 30, the first light detection sensors 40 of the first light detection regions 30A absorb and convert into charges Q1 more of the first wavelength light 26A than the second wavelength light 28A. The second light detection sensors 42 of the second light detection regions 30B absorb and convert into charges Q2 more of the second wavelength light 28A than the first wavelength light 26A.

Then, as illustrated in FIG. 7, the gates of the TFT switches 70, 72 are applied with an ON signal in sequence through the scan lines 124. The TFT switches 70, 72 are thereby switched ON in sequence, and the charges Q1 generated by the first light detection sensors 40 flow as electrical signals through the first signal lines 126A, and the charges Q2 generated by the second light detection sensors 42 flow as electrical signals through the second signal lines 126B.

Based on the electrical signals that have flowed in the first signal lines 126A and the second signal lines 126B, the signal detection circuit 200 detects the charge amounts generated in the first light detection sensors 40 and the second light detection sensors 42 as data for each of the pixels 120, 122 configuring images. The signal processor 204 separates the data of each of the pixels 120, 122 detected by the signal detection circuit 200 into the image data from each of the first signal lines 126A and the image data from each of the second signal lines 126B and subjects the data to specific processing. Image data representing a radiographic image (low voltage image) expressing the low energy radiation X1 incident to the radiation detector 20 and image data representing a radiographic image (high voltage image) expressing the high energy radiation X2 are accordingly both obtainable at the same time.

Consequently, it is possible to obtain two radiographic images, the low voltage image and the high voltage image, for a single time of radiation X irradiation.

As stated above, plural of the first light detection sensors 40 that absorb the first wavelength light 26A and plural of the second light detection sensors 42 that absorb the second wavelength light 28A are disposed within the same plane. The thickness of the organic photoelectric conversion layer 30 can accordingly be made thinner than when the first light detection sensors 40 and the second light detection sensors 42 are configured with a double layer structure, and hence the radiation detector 20 can also be made thinner overall. The first organic photoelectric conversion layer 54 of the first light detection sensors 40 and the second organic photoelectric conversion layer 64 of the second light detection sensors 42 are both configured by organic materials. It is accordingly possible to dispose thinner first light detection sensors 40 and second light detection sensors 42 in the same plane than would be the case for other materials.

Moreover, in the radiation detector 20 according to the first exemplary embodiment of the present invention, the radiation X incident face is on the TFT substrate 32 side, and so the radiation X is irradiated in sequence to the TFT substrate 32, the organic photoelectric conversion layer 30 and the scintillator layer 24. When this occurs, the radiation X is first irradiated onto a scintillator portion in the scintillator layer 24 on the organic photoelectric conversion layer 30 side, and accordingly the scintillator portion on the organic photoelectric conversion layer 30 side mainly absorbs the radiation X and emits light. Since the scintillator portion in the scintillator layer 24 that mainly absorbs the radiation X and emits light is on the organic photoelectric conversion layer 30 side, there is a close separation between this scintillator portion and the organic photoelectric conversion layer 30, and more light is absorbed by the organic photoelectric conversion layer 30, and the sensitivity is raised.

The organic photoelectric conversion layer 30 has a reduced number of manufacturing processes in comparison to double layer structures and so yield is raised. Moreover, in cases in which the organic photoelectric conversion layer 30 is formed with a double layer structure, one of the layers lowers the light reception efficiency of the other layer. However in a single layer structure such as in the present exemplary embodiment the light reception efficiency is the same for the first light detection sensors 40 and the second light detection sensors 42. There are also better electrical characteristics and less noise generated than in a double layer structure.

### Second Exemplary Embodiment

Explanation follows regarding a radiation detector according to a second exemplary embodiment of the present invention.

—Radiation Detector Configuration—

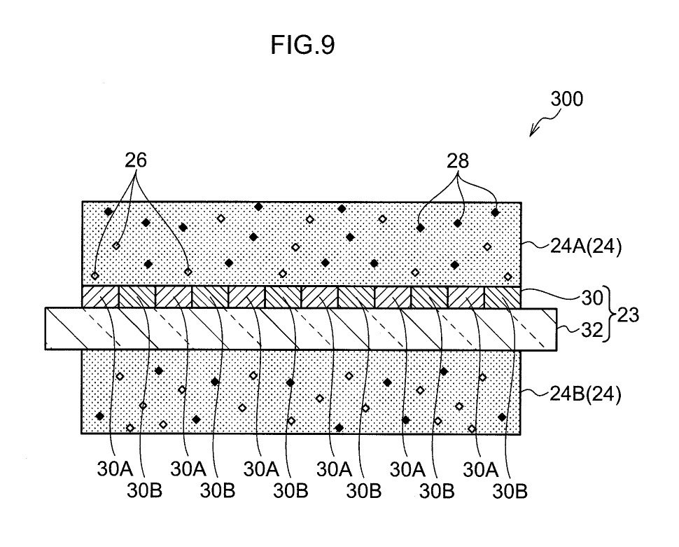

FIG. 9 is a cross-section illustrating a cross-sectional configuration of a radiation detector 300 according to the second exemplary embodiment of the present invention.

As illustrated in FIG. 9, the configuration of the radiation detector 300 according to a second exemplary embodiment of the present invention is similar to the configuration illustrated in FIG. 3 and explained in the first exemplary embodiment. The TFT substrate 32 has radiation transmitting properties and light transmitting properties, and the scintillator layer 24 is configured divided into two layers. Specifically, the radiation detector 300 is equipped with a first scintillator layer 24A disposed on the top face of an organic photoelectric conversion layer 30, and a second scintillator layer 24B disposed on a bottom face of the TFT substrate 32 that has light transmitting properties.

Note that in the present exemplary embodiment, “radiation transmitting properties” means a property of transmitting a radiation amount of at least 1% of the radiation amount of incident radiation X or greater. “Light transmitting properties” means a property of transmitting a light amount of at least 1% of the light amount of light emitted from the second scintillator layer 24B or greater.

—Operation—

According to such a configuration, the light emitted by the first scintillator layer 24A directly hits the organic photoelectric conversion layer 30, and the light emitted by the second scintillator layer 24B hits the organic photoelectric conversion layer 30 after being transmitted through the TFT substrate 32 that has light transmitting properties. The second scintillator layer 24B accordingly serves a similar role to the first scintillator layer 24A, and the thickness of the first scintillator layer 24A can be made thinner by the amount of the second scintillator layer 24B disposed on the TFT substrate 32 side. When the thickness of the first scintillator layer 24A is made thin, even suppose the radiation X is incident in sequence to the first scintillator layer 24A, the organic photoelectric conversion layer 30, the TFT substrate 32 and the second scintillator layer 24B, there is a closer separation between the scintillator portion that mainly absorbs the radiation X and emits light in the first scintillator layer 24A and the organic photoelectric conversion layer 30, more light is absorbed by the organic photoelectric conversion layer 30 and the sensitivity is raised.

### Third Exemplary Embodiment

Explanation follows regarding a radiation detector according to a third exemplary embodiment of the present invention.

—Radiation Detector Configuration—

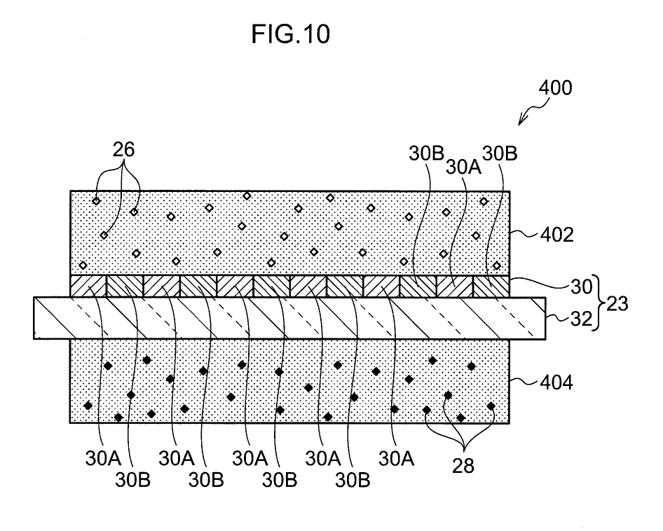

FIG. 10 is a cross-section illustrating a cross-sectional configuration of a radiation detector 400 according to a third exemplary embodiment of the present invention.

As illustrated in FIG. 10, the radiation detector 400 according to the third exemplary embodiment of the present invention is similar to that of the second exemplary embodiment, however differs in the configuration of the scintillator layer.

More specifically, a light detection substrate 23 is interposed between a first scintillator layer 402 and a second scintillator layer 404. The first scintillator layer 402 and the second scintillator layer 404 are configured with phosphor materials having mutually different sensitivities (K absorption edge and light emission wavelength) to the radiation X. Specifically, the first scintillator layer 402 is configured with a first phosphor material 26 with radiation absorption ratio μ that does not have a K absorption edge in a high energy portion, namely in which there is no discontinuous increase in the absorption ratio μ in the high energy portion, for capturing a low voltage image of soft tissue expressing low energy radiation out of the radiation X that has been transmitted through a patient 14. The second scintillator layer 404 is configured with a second phosphor material 28 with radiation absorption ratio μ higher in the high energy portion than that of the first phosphor material 26, for capturing a high voltage image of hard tissue expressing high energy radiation out of the radiation X that has been transmitted through the patient 14.

The same materials as in the first exemplary embodiment may be employed as the first phosphor material 26 and the second phosphor material 28 of the third exemplary embodiment. However, from the perspective of obtaining high image quality, preferably a base material of CsI or CsBr is selected, with these having columnar structures and not being preferable in the first exemplary embodiment. In particular, the first scintillator layer 402 is more preferably configured with the first phosphor material 26 of a columnar structure due to the requirements for high image quality in a low voltage image to enable fine portions of soft tissue to be sufficiently expressed. Specifically, by configuring the first scintillator layer 402 with a columnar structure, light converted in the first scintillator layer 402 can progress while being reflected at the boundaries of the columnar structure in a columnar structure, and light scattering is reduced. Consequently, the received light amount by first light detection sensors 40 of an organic photoelectric conversion layer 30 is greater, and hence a low voltage image of high image quality can be obtained. Moreover, a combination of blue light emitting BaFx:Eu for the first phosphor material 26 and green light emitting Gd₂O₂S:Tb for the second phosphor material 28 is preferable as the combination of the first phosphor material 26 and the second phosphor material 28.

The light emitted by the first scintillator layer 402 and the second scintillator layer 404 is light received by the light detection substrate 23. The light detection substrate 23 is equipped with the organic photoelectric conversion layer 30 and a TFT substrate 32.

The organic photoelectric conversion layer 30 is interposed between the first scintillator layer 402 and the TFT substrate 32, and the light emitted by the first scintillator layer 402 and the second scintillator layer 404 is light that is received and converted into charges. Specifically, configuration is made with plural first light detection regions 30A and plural second light detection regions 30B of which at least a portion are configured with organic materials having mutually different light absorption characteristics, disposed in the same plane. The plural first light detection regions 30A and the plural second light detection regions 30B are for example disposed mutually adjacent to each other in the same flat plane at a 1:1 ratio in a staggered formation.

The second scintillator layer 404 described above is disposed on the bottom face (back face) of the TFT substrate 32 that has radiation transmitting properties to transmit radiation X through to the second scintillator layer 404, and also has light transmitting properties to let light emitted by the second scintillator layer 404 pass through.

Note that in the present exemplary embodiment, “radiation transmitting properties” means a property of transmitting a radiation amount of at least 1% of the radiation amount of incident radiation X or greater. “Light transmitting properties” means a property of transmitting a light amount of at least 1% of the light amount of light emitted from the second scintillator layer 404 or greater.

An active layer 104 of TFT switches 70 in the TFT substrate 32 of the present exemplary embodiment is also for example preferably formed from an amorphous transparent oxide material such as an oxide material including at least one of In, Ga and Zn. Configuring the active layer 104 of the TFT switches 70 with an amorphous transparent oxide material means that radiation such as X-rays is not absorbed, or any absorption is restricted to an extremely minute amount, thereby enabling effective suppression of noise generation. The light from the second scintillator layer 404 can also be sufficiently transmitted.

—Operation—

Explanation follows regarding operation of the radiation detector 400 according to a third exemplary embodiment of the present invention.

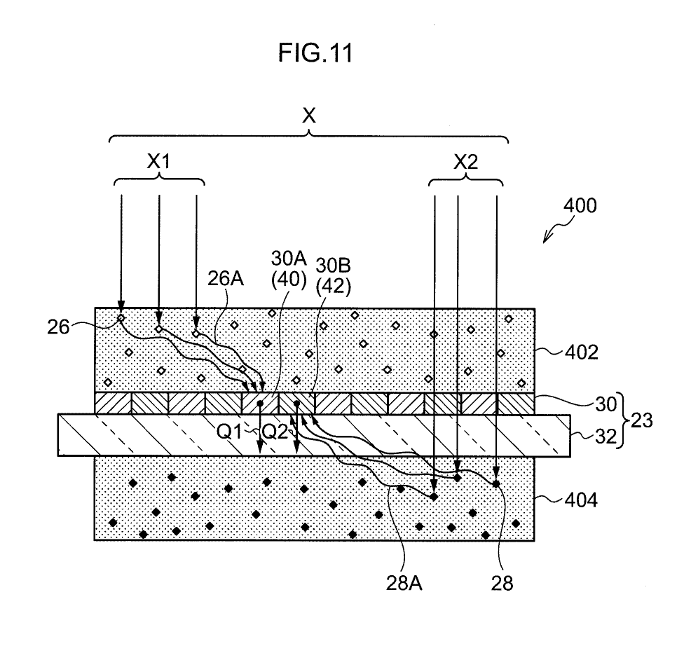

FIG. 11 is an explanatory diagram of the operation of the radiation detector 400 according to a third exemplary embodiment of the present invention.

The configuration of the radiation detector 400 according to a third exemplary embodiment of the present invention, as explained above, is configured by layers stacked along a radiation incident direction and includes: the first scintillator layer 402 that is mainly sensitive to the low energy radiation X1 in incident radiation X and converts the radiation X into the light 26A of the first wavelength; the second scintillator layer 404 that is mainly sensitive to the high energy radiation X2 rather than the low energy radiation in the radiation X and converts the radiation X into light 28A of a second wavelength different from the first wavelength; the organic photoelectric conversion layer 30 configured by disposing in the same plane plural first light detection sensors 40 that are configured from an organic material and that absorb and convert into charge more of the first wavelength light 26A than the second wavelength light 28A, and plural second light detection sensors 42 that are configured from a second organic material different from a first organic material and that absorb and convert into charge more of the second wavelength light 28A than the first wavelength light 26A; and the TFT substrate 32 that has light transmitting properties interposed between the first scintillator layer 402 and the second scintillator layer 404 with the organic photoelectric conversion layer 30 formed on a face of the TFT substrate 32 and the TFT substrate 32 formed with transistors that read the charges that have been generated in the organic photoelectric conversion layer 30.

In such a configuration, when radiographic image capture is performed the radiation X that has been transmitted through the patient 14 is irradiated onto the radiation detector 20. The radiation X that has been transmitted through the patient 14 contains the low energy component X1 and the high energy component X2.

In the radiation detector 400 according to a third exemplary embodiment of the present invention, since the radiation X incident face is the first scintillator layer 402 side of the radiation detector 400, the irradiated radiation X first hits the first scintillator layer 402 in the radiation detector 400 configuration. Then, after being transmitted through the organic photoelectric conversion layer 30 and the TFT substrate 32 configuring the light detection substrate 23, the radiation X hits the second scintillator layer 404.

When the radiation X hits the first scintillator layer 402, the first phosphor material 26 of the first scintillator layer 402 is mainly sensitive to the low energy radiation X1 in the incident radiation X and converts the radiation X into the light 26A with a peak at the first wavelength. When the radiation X hits the second scintillator layer 404, the second phosphor material 28 of the second scintillator layer 404 is mainly sensitive to the high energy radiation X2 rather than low energy in the incident radiation X and converts the radiation X into the light 28A with a peak at the second wavelength different from the first wavelength. The first wavelength light 26A and the second wavelength light 28A are emitted from the first scintillator layer 402 and the second scintillator layer 404 and hit the organic photoelectric conversion layer 30.

When the first wavelength light 26A and the second wavelength light 28A hit the organic photoelectric conversion layer 30, the first light detection sensors 40 of the first light detection regions 30A absorb and convert into charges Q1 more of the first wavelength light 26A than the second wavelength light 28A. The second light detection sensors 42 of the second light detection regions 30B absorb and convert into charges Q2 more of the second wavelength light 28A than the first wavelength light 26A.

Then, as illustrated in FIG. 7, the gates of the TFT switches 70, 72 are applied with an ON signal in sequence through the scan lines 124. The TFT switches 70, 72 are thereby switched ON in sequence, and the charges Q1 generated by the first light detection sensors 40 flow as electrical signals through the first signal lines 126A, and the charges Q2 generated by the second light detection sensors 42 flow as electrical signals through the second signal lines 126B.

Based on the electrical signals that have flowed in the first signal lines 126A and the second signal lines 126B, the signal detection circuit 200 detects the charge amounts generated in the first light detection sensors 40 and the second light detection sensors 42 as data for each of the pixels 120, 122 configuring images. The signal processor 204 separates the data of each of the pixels 120, 122 detected by the signal detection circuit 200 into the image data from each of the first signal lines 126A and the image data from each of the second signal lines 126B and subjects the data to specific processing. Image data representing a radiographic image (low voltage image) expressing the low energy radiation X1 incident to the radiation detector 400 and image data representing a radiographic image (high voltage image) expressing the high energy radiation X2 are accordingly both obtainable at the same time.

Consequently, it is possible to obtain two radiographic images, the low voltage image and the high voltage image, for a single time of radiation X irradiation.

As stated above, plural of the first light detection sensors 40 that absorb the first wavelength light 26A and plural of the second light detection sensors 42 that absorb the second wavelength light 28A are disposed within the same plane. The thickness of the organic photoelectric conversion layer 30 can accordingly be made thinner than when the first light detection sensors 40 and the second light detection sensors 42 are configured with a double layer structure, and hence the radiation detector 400 can also be made thinner overall. The first organic photoelectric conversion layer 54 of the first light detection sensors 40 and the second organic photoelectric conversion layer 64 of the second light detection sensors 42 are also both configured by organic materials. It is accordingly possible to dispose thinner first light detection sensors 40 and second light detection sensors 42 in the same plane than would be the case for other materials.

The organic photoelectric conversion layer 30 has a reduced number of manufacturing processes in comparison to double layer structures and so yield is raised. Moreover, in cases in which the organic photoelectric conversion layer 30 is formed with a double layer structure, one of the layers lowers the light reception efficiency of the other layer. However in a single layer structure such as in the present exemplary embodiment the light reception efficiency is the same for the first light detection sensors 40 and the second light detection sensors 42. There are also better electrical characteristics and less noise generated than in a double layer structure.

Moreover, the thickness of the first scintillator layer 402 can be made thinner than in cases, such as in the first exemplary embodiment and the second exemplary embodiment, in which not only the first phosphor material 26 but also the second phosphor material 28 is blended into the first scintillator layer 402. By making a thin thickness for the first scintillator layer 402, then even though the radiation X is irradiated in sequence to the first scintillator layer 402, the organic photoelectric conversion layer 30, the TFT substrate 32 and the second scintillator layer 404, the separation is kept close between the scintillator portion in the first scintillator layer 402 that mainly absorbs the radiation X and generates light and the organic photoelectric conversion layer 30. More light is accordingly absorbed by the organic photoelectric conversion layer 30 and sensitivity is raised.

### Modified Examples

The present invention has been explained in detail with respect to the specific first to third exemplary embodiments, however the present invention is not limited by these exemplary embodiments. It will be clear to a person of skill in the art that various other exemplary embodiments are possible within the scope of the present invention, and for example appropriate combinations may be implemented from the plural exemplary embodiments described above. Appropriate combinations may also be made with the following modified examples.

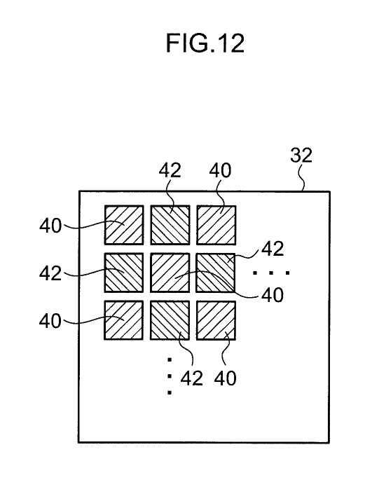

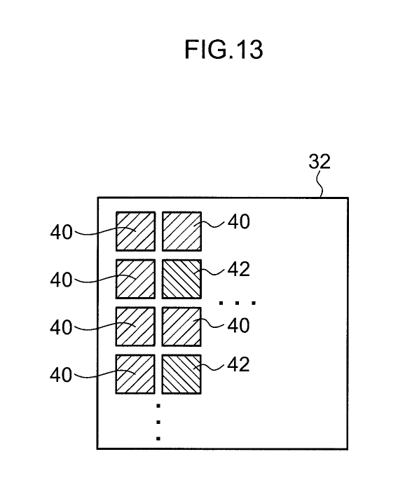

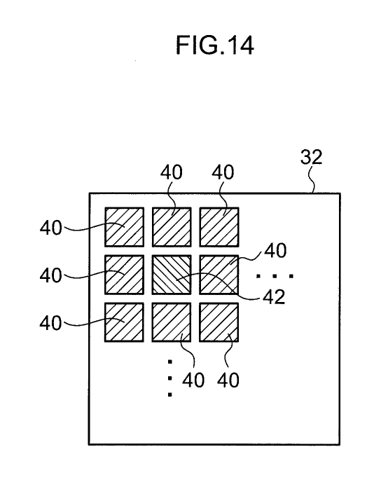

For example, in the first exemplary embodiment to the third exemplary embodiment of the present invention, plural of the first light detection sensors 40 and plural of the second light detection sensors 42 are, as illustrated in FIG. 12, disposed mutually adjacent to each other at a ratio of 1:1, and so a low voltage image and a high voltage image having the same resolution as each other are obtained. However the placement ratio of the first light detection sensors 40 and the second light detection sensors 42 can be varied. For example, more of the first light detection sensors 40 may be disposed than the second light detection sensors 42. The placement ratio of the first light detection sensors and the second light detection sensors 42 may accordingly be a ratio of 3:1 as illustrated in FIG. 13 or a ratio of 8:1 as illustrated in FIG. 14.

By thus configuring with a larger number of first light detection sensors 40 that absorb the first wavelength light 26A that has been converted from radiation X by sensitivity mainly to the low energy radiation X1 out of the incident radiation X, and convert the absorbed light into charges Q1, the number of pixels for low voltage images obtained from the first light detection sensors 40 is increased, and resolution of the low voltage image can be raised. Raising the resolution of a low voltage image representing soft tissue of the patient 14 enables fine structures of the soft tissue to be reliably visually checked.

The placement illustrated in FIG. 14 has the second light detection sensors 42 surrounded in four directions by plural first light detection sensors 40. Consequently, when supplementing lacking pixels in a low voltage image, the lacking pixel is at the center in four directions, enabling supplementing to be performed at good precision for the center pixel using the pixels 120 in the four directions.

Moreover, explanation has been given for a case in which two signal lines configure each of the signal lines 126 illustrated in FIG. 7, these being the first signal lines 126A corresponding to the pixels 120 and the second signal lines 126B corresponding to the pixels 122, however a single signal line may be employed. In such cases, the signal processor 204 performs processing to sort the data of each of the detected pixels 120, 122 in the signal detection circuit 200 into the pixels 120 and the pixels 122.

In FIG. 7, each of the first signal lines 126A and each of the second signal lines 126B are connected to a single signal detection circuit 200, however two signal detection circuits 200 may be provided, with the first signal lines 126A and the second signal lines 126B connected to separate signal detection circuits 200. According to this method, a general signal detection circuit that is used for the light detection substrate for detecting a single radiographic image can be used.

Moreover, explanation has been given of a case in which single first light detection sensors 40 or second light detection sensors 42 respectively configure single pixels of a radiographic image representing radiation X that has been transmitted through the patient 14, however they may respectively configure plural pixels. Conversely, plural of the first light detection sensors 40 or the second light detection sensors 42 may be employed to configure a single pixel of a radiographic image.

In the first exemplary embodiment, explanation has been given of a case in which the radiation detector 20 to detect the radiation X that has been transmitted through the patient 14 and the control board 22 are provided inside the casing 16 in sequence from the incident face 18 side of the casing 16 onto which the radiation X is irradiated. However the following may be housed in sequence from the incident face 18 side onto which the radiation X is irradiated: a grid to remove scattering radiation of the radiation X that occurs during transmission through the patient 14, the radiation detector 20 and a lead plate to absorb back scatting radiation from the radiation X.

In the first exemplary embodiment, explanation has been given of a case in which the shape of the casing 16 is a rectangular flat plate shape, however there is no particular limitation thereto, and the shape may for example be a square shape or circular shape viewed face on.

Moreover, explanation has been given in the first exemplary embodiment of a case configured with a single control board 22, however the present invention is not limited by the exemplary embodiment and the control board 22 may be split into plural boards for each function. Explanation has also been given of a case in which the control board 22 is placed alongside the radiation detector 20 in the vertical direction (the thickness direction of the casing 16), however the control board 22 may be placed alongside the radiation detector 20 in the horizontal direction.

The radiation X is also not limited to X-rays, and a rays, 0 rays, y rays, an electron beam or ultraviolet radiation may also be employed.

Moreover, explanation has been given of a case in which the radiographic image capture device is the portable electronic cassette 10, however the radiographic image capture device may be a non-portable large radiographic image capture device. In the first exemplary embodiment, the incident face to the radiation X is the substrate 32 side, however the incident face may be the scintillator layer 24 side. Explanation has been given in the first exemplary embodiment of a case in which the organic photoelectric conversion layer 30 and the scintillator layer 24 are stacked as layers in sequence from the TFT substrate 32 side as the incident face to the radiation X. However the sequence of layers may be changed as appropriate, and configuration may be made for example with the TFT substrate 32 and the organic photoelectric conversion layer 30 stacked as layers with the scintillator layer 24 as the incident face to the radiation X. In the third exemplary embodiment the incident face to the radiation X is the scintillator layer 24A side, however it may be configured as the second scintillator layer 24B side. Note that the content disclosed in Japanese Patent Application No. 2010-169444 and Japanese Patent Application No. 2010-168583 are incorporated by reference in their entirety in the present specification.

All cited documents, patent applications and technical standards mentioned in the present specification are incorporated by reference in the present specification to the same extent as if the individual cited documents, patent applications and technical standards were specifically and individually incorporated by reference in the present specification.

What is claimed is:

1. A radiation detector comprising:
a first scintillator layer containing a blend of a first phosphor material that is mainly sensitive to low energy radiation in incident radiation and converts the radiation into light of a first wavelength, and a second phosphor material that is more sensitive to high energy than low energy radiation in the radiation and converts the radiation into light of a second wavelength different from the first wavelength;
an organic photoelectric conversion layer configured by disposing in the same plane a plurality of first light detection sensors that are configured from a first organic material and that absorb and convert into charge more of the first wavelength light than the second wavelength light, and a plurality of second light detection sensors that are configured from a second organic material different from the first organic material and that absorb and convert into charge more of the second wavelength light than the first wavelength light; and
a substrate, the organic photoelectric conversion layer being disposed on the substrate and the substrate being formed with transistors that read the charges that have been generated in the organic photoelectric conversion layer, wherein
the first scintillator layer, the organic photoelectric conversion layer and the substrate are layered along a radiation incident direction.

2. The radiation detector of claim 1 wherein the substrate side is set as the radiation incident face.

3. The radiation detector of claim 1 wherein:
the first light detection sensor transmits light of the second wavelength and absorbs light of the first wavelength; and
the second light detection sensor transmits light of the first wavelength and absorbs light of the second wavelength.

4. The radiation detector of claim 1 wherein the first wavelength is a blue light wavelength and the second wavelength is a green light wavelength.

5. The radiation detector of claim 1 wherein:
an active layer of the transistor is configured with an amorphous oxide material; and
the substrate is configured with a plastic resin.

6. The radiation detector of claim 1 wherein:
the substrate has light transmitting properties; and
a second scintillator layer configured from the same material as the first scintillator layer is disposed on the substrate.

7. The radiation detector of claim 6 wherein the first scintillator layer and the second scintillator layer contain as the first phosphor material and the second phosphor material Tb doped Gd₂O₂S that converts radiation into green light and Eu doped BaFX that converts the radiation into blue light, wherein X is a halogen.

8. The radiation detector of claim 1 wherein the total light receiving surface area of the first light detection sensors and the second light detection sensors are the same as each other.

9. The radiation detector of claim 8 wherein the first light detection sensors and the second light detection sensors configure respective single pixels of a radiographic image expressing radiation that has been transmitted through an imaging subject.

10. The radiation detector of claim 9 wherein a plurality of the first light detection sensors and a plurality of the second light detection sensors are disposed at a ratio of 1 to 1 so as to be adjacent to each other.

11. The radiation detector of claim 9 wherein there are more of the first light detection sensors disposed than the second light detection sensors.

12. The radiation detector of claim 11 wherein the second light detection sensors are disposed surrounded in four directions by a plurality of the first light detection sensors.

13. A radiation detector comprising:
a first scintillator layer that is mainly sensitive to low energy radiation in incident radiation and converts the radiation into light of a first wavelength;
a second scintillator layer that is more sensitive to high energy than low energy radiation in the radiation and converts the radiation into light of a second wavelength different from the first wavelength;
an organic photoelectric conversion layer configured by disposing in the same plane a plurality of first light detection sensors that are configured from a first organic material and that absorb and convert into charge more of the first wavelength light than the second wavelength light, and a plurality of second light detection sensors that are configured from a second organic material different from the first organic material and that absorb and convert into charge more of the second wavelength light than the first wavelength light; and
a substrate with light transmitting properties interposed between the first scintillator layer and the second scintillator layer with the organic photoelectric conversion layer formed on a face of the substrate and the substrate formed with transistors that read the charges that have been generated in the organic photoelectric conversion layer,
wherein the first scintillator layer, the second scintillator layer, the organic photoelectric conversion layer and the substrate are layered along a radiation incident direction.

14. The radiation detector of claim 13 wherein:
the first light detection sensor transmits light of the second wavelength and absorbs light of the first wavelength; and
the second light detection sensor transmits light of the first wavelength and absorbs light of the second wavelength.

15. The radiation detector of claim 13 wherein the first wavelength is a blue light wavelength and the second wavelength is a green light wavelength.

16. The radiation detector of claim 13 wherein:
the first scintillator layer is configured with Eu doped BaFX that converts the radiation into blue light, wherein X is a halogen; and
the second scintillator layer is configured with Tb doped Gd₂O₂S that converts radiation into green light.

17. The radiation detector of claim 13 wherein:
an active layer of the transistor is configured with an amorphous oxide material; and
the substrate is configured with a plastic resin.

18. The radiation detector of claim 13 wherein the first scintillator layer has a columnar structure.

19. The radiation detector of claim 13 wherein the total light receiving surface area of the first light detection sensors and the second light detection sensors are the same as each other.

20. The radiation detector of claim 19 wherein the first light detection sensors and the second light detection sensors configure respective single pixels of a radiographic image expressing radiation that has been transmitted through an imaging subject.

21. The radiation detector of claim 20 wherein a plurality of the first light detection sensors and a plurality of the second light detection sensors are disposed at a ratio of 1 to 1 so as to be adjacent to each other.

22. The radiation detector of claim 20 wherein there are more of the first light detection sensors disposed than the second light detection sensors.

23. The radiation detector of claim 22 wherein the second light detection sensors are disposed surrounded in four directions by a plurality of the first light detection sensors.

24. A radiation detector manufacturing method that is a manufacturing method for the radiation detector of claim 1, the radiation detector manufacturing method comprising:
disposing a plurality of the first light detection sensors and a plurality of the second light detection sensors of the organic photoelectric conversion layer on the substrate in the same plane as each other using an inkjet method.

25. A radiation detector manufacturing method that is a manufacturing method for the radiation detector of claim 13, the radiation detector manufacturing method comprising:
disposing a plurality of the first light detection sensors and a plurality of the second light detection sensors of the organic photoelectric conversion layer on the substrate in the same plane as each other using an inkjet method.
